(19) United States
(12) Patent Application Publication
(10) Pub. No.: US 2026/0039317 A1
(43) Pub. Date: Feb. 5, 2026

(54) SOFT DECISION APPARATUS, SOFT DECISION METHOD AND PROGRAM

(71) Applicant: NIPPON TELEGRAPH AND TELEPHONE CORPORATION, Tokyo (JP)

(72) Inventors: Hiroki TANIGUCHI, Musashino-shi (JP); Shuto YAMAMOTO, Musashino-shi (JP); Masanori NAKAMURA, Musashino-shi (JP); Akira MASUDA, Musashino-shi (JP); Yoshiaki KISAKA, Musashino-shi (JP)

(73) Assignee: NIPPON TELEGRAPH AND TELEPHONE CORPORATION, Tokyo (JP)

(21) Appl. No.: 19/099,434

(22) PCT Filed: Jan. 17, 2023
(86) PCT No.: PCT/JP2023/001097

§ 371 Date: Jan. 28, 2025

(30) Foreign Application Priority Data
Aug. 9, 2022 (WO) PCT/JP2022/030392

(51) Int. Cl. H03M 13/41; H04B 17/318

(52) U.S. Cl. CPC H03M 13/41; H04B 17/318

(57) ABSTRACT

Provided is a soft decision device that performs a soft decision on an (n+1)th symbol of a transmission signal with a symbol multilevel degree of m, the soft decision device including: a control unit that estimates a branch metric, which is a distance that is obtained by a Viterbi algorithm, is in a distance function, and indicates a likelihood of transition from an nth symbol of the transmission signal to each candidate for the (n+1)th symbol, based on a received signal and an estimated transfer function that is an estimation result of a transfer function of a transmission line, estimates a path metric, which is a sum of a distance that is obtained by the Viterbi algorithm, is in a distance function, and indicates a likelihood that each candidate for the (n+1)th symbol of the transmission signal is a symbol of the transmission signal and a distance of a predetermined remaining path of the transmission signal, based on a result of the branch metric estimation process, and estimates a likelihood that a kth bit in the (n+1)th symbol of the transmission signal is a predetermined bit by using the path metric of each candidate for the (n+1)th symbol of the transmission signal.

This application claims priority on the basis of PCT/JP2022/030392, filed on Aug. 9, 2022, the content of which is incorporated herein by reference.

### TECHNICAL FIELD

The present invention relates to a soft decision apparatus, a soft decision method and a program.

### BACKGROUND ART

In order to cope with the increase in network traffic in recent years, studies are underway to increase the speed and distance of optical transmission systems.

### CITATION LIST

### Non Patent Document

Non Patent Document 1: D. D. Falconer, et al., ‘Adaptive channel memory truncation for maximum likelihood sequence estimation’, The Bell System Technical Journal, vol. 52, No. 9, pp. 1541-1562 (1973)

### SUMMARY OF INVENTION

### Technical Problem

However, as optical transmission systems increase in speed and distance, signal distortion and noise increase. Therefore, there is a need for a technology to estimate symbols of a transmission signal, which is an optical signal transmitted by a transmitter, and it has been proposed to estimate the symbols of the transmission signal using an inverse function of a transfer function of a transmission line. However, estimation using the proposed technology sometimes had low accuracy.

In view of the above circumstances, an object of the present invention is to provide a technology to estimate symbols of a transmission signal with higher accuracy.

### Solution to Problem

According to an aspect of the present invention, there is provided a soft decision device that performs a soft decision on a main symbol that is an (n+1)th symbol (n is an integer from 1 to N, N is an integer of 1 or more) of a transmission signal with a symbol multilevel degree of m (m is an integer of 2 or more), the soft decision device including: a control unit that executes a branch metric estimation process of estimating a branch metric, which is a distance that is obtained by a Viterbi algorithm, is indicated by a predetermined distance function, and indicates a likelihood of transition from an nth symbol of the transmission signal to each candidate for the (n+1)th symbol, based on an estimated transfer function that is a previously obtained estimation result of a transfer function of a transmission line through which the transmission signal propagates and a received signal that is a result of reception of the transmission signal, a path metric estimation process of estimating a path metric, which is a sum of a distance that is obtained by the Viterbi algorithm, is indicated by a predetermined distance function, and indicates a likelihood that each candidate for the (n+1)th symbol of the transmission signal is a symbol of the transmission signal and a distance of first to nth remaining paths of the transmission signal, based on a result of the branch metric estimation process, and a bit likelihood estimation process of estimating a likelihood that a kth bit (k is an integer from 1 to m) in the (n+1)th symbol of the transmission signal is a predetermined bit by using the path metric of each candidate for the (n+1)th symbol of the transmission signal obtained by the path metric estimation process, and without using path metrics other than the path metric of each candidate for the (n+1)th symbol of the transmission signal, in which the control unit acquires the likelihood estimated by the bit likelihood estimation process as a result of the soft decision.

According to another aspect of the present invention, there is provided a soft decision method for performing a soft decision on a main symbol that is an (n+1)th symbol (n is an integer from 1 to N, N is an integer of 1 or more) of a transmission signal with a symbol multilevel degree of m (m is an integer of 2 or more), the soft decision method including: a control step of executing a branch metric estimation process of estimating a branch metric, which is a distance that is obtained by a Viterbi algorithm, is indicated by a predetermined distance function, and indicates a likelihood of transition from an nth symbol of the transmission signal to each candidate for the (n+1)th symbol, based on an estimated transfer function that is a previously obtained estimation result of a transfer function of a transmission line through which the transmission signal propagates and a received signal that is a result of reception of the transmission signal, a path metric estimation process of estimating a path metric, which is a sum of a distance that is obtained by the Viterbi algorithm, is indicated by a predetermined distance function, and indicates a likelihood that each candidate for the (n+1)th symbol of the transmission signal is a symbol of the transmission signal and a distance of first to nth remaining paths of the transmission signal, based on a result of the branch metric estimation process, and a bit likelihood estimation process of estimating a likelihood that a kth bit (k is an integer from 1 to m) in the (n+1)th symbol of the transmission signal is a predetermined bit by using the path metric of each candidate for the (n+1)th symbol of the transmission signal obtained by the path metric estimation process, and without using path metrics other than the path metric of each candidate for the (n+1)th symbol of the transmission signal, in which the control step includes acquiring the likelihood estimated by the bit likelihood estimation process as a result of the soft decision.

According to still another aspect of the present invention, there is provided a program for causing a computer to function as the soft decision device.

### Advantageous Effects of Invention

According to the present invention, it is possible to estimate symbols of a transmission signal with higher accuracy.

### BRIEF DESCRIPTION OF DRAWINGS

FIG. 1 An explanatory diagram illustrating an optical transmission system according to an embodiment.

FIG. 2 An explanatory diagram illustrating the Viterbi algorithm in the embodiment.

FIG. 3 A diagram showing an example of a hardware configuration of a soft decision device according to the embodiment.

FIG. 4 A flowchart showing a first example of a flow of processing executed by the soft decision device according to the embodiment.

FIG. 5 A flowchart showing a second example of a flow of processing executed by the soft decision device according to the embodiment.

FIG. 6 A first diagram showing an example of experimental results in the embodiment.

FIG. 7 A second diagram showing an example of experimental results in the embodiment.

FIG. 8 A diagram showing an example of a configuration of a control unit according to the embodiment.

FIG. 9 A flowchart showing a third example of a flow of processing executed by the soft decision device according to the embodiment.

FIG. 10 A diagram showing an example of a bit likelihood histogram in the embodiment.

FIG. 11 A third diagram showing an example of experimental results in the embodiment.

### DESCRIPTION OF EMBODIMENTS

### First Embodiment

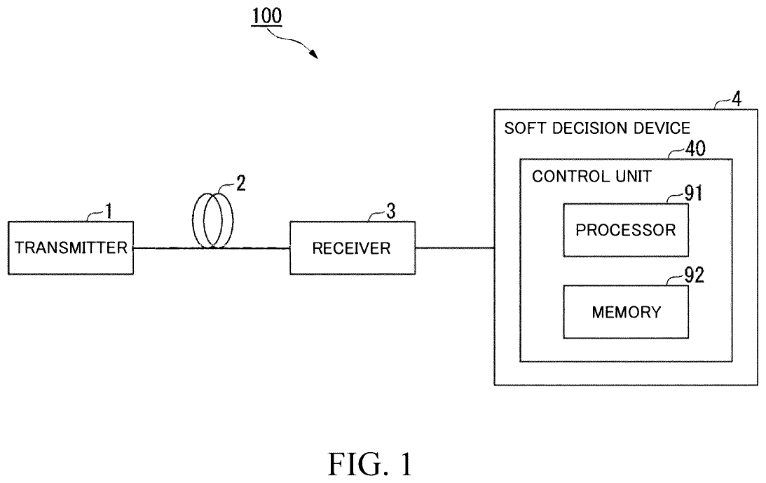

FIG. 1 is an explanatory diagram illustrating an optical transmission system 100 according to an embodiment. The optical transmission system 100 includes a transmitter 1, a transmission line 2, a receiver 3, and a soft decision device 4. The transmitter 1 transmits an optical signal. Hereinafter, the optical signal transmitted by the transmitter 1 will be referred to as a transmission signal. In the optical transmission system 100, a symbol multilevel degree of the transmission signal was m (m is an integer of 1 or more). Hereinafter, the symbol of the transmission signal will be referred to as a main symbol.

The transmission line 2 is a transmission line, such as an optical fiber, through which an optical signal propagates. The transmission signal transmitted by the transmitter 1 propagates through the transmission line 2 and reaches the receiver 3. The receiver 3 receives the optical signal propagated through the transmission line 2. Hereinafter, the result of the receiver receiving the optical signal propagated through the transmission line 2 will be referred to as a received signal.

When the transfer function of the transmission line 2 is expressed as a vector H={h₁, . . . , hₗ}, a received signal yₙ is xₙ·H+Wₙ. H is a vector whose elements are weighting coefficients. Therefore, h1, . . . , hl are all weighting coefficients. l is a storage length. That is, l is a time spread of the transfer function. xₙ is a symbol string indicating a transmission signal, and is a symbol string having symbols from the (n−l+1)th symbol to the nth symbol. A dot (·) means an inner product. Wₙ represents white noise added to the optical signal by propagating through the transmission line 2.

The soft decision device 4 performs a soft decision on the (n+1)th (n is an integer from 1 to N, N is an integer of 1 or more) symbol of the transmission signal. The soft decision device 4 includes a control unit 40 including a processor 91 such as a central processing unit (CPU) and a memory 92, which are connected by a bus, and executes a program.

### <Viterbi Algorithm>

The soft decision made by the soft decision device 4 uses quantities defined in the Viterbi algorithm. Therefore, before describing the soft decision made by the soft decision device 4, the Viterbi algorithm will be described just in case. For the sake of simplicity, an example will be described in which the storage length l=3 and the symbol multilevel degree m=2. Further, a case where the signal is a series of two bits, 0 and 1, will be described as an example.

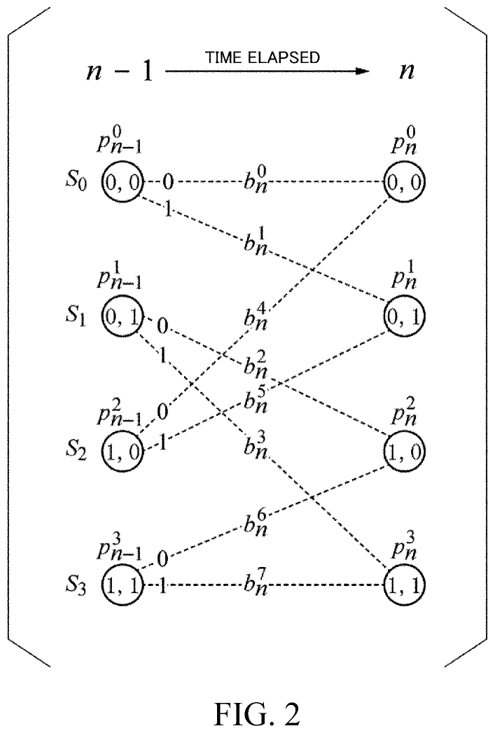

FIG. 2 is an explanatory diagram illustrating the Viterbi algorithm in the embodiment. More specifically, FIG. 2 is a trellis diagram illustrating the Viterbi algorithm.

Since the symbol multilevel degree m=2 and the storage length l=3, there are (R+1) candidates for the state of the transmission signal at each time n. R is the value obtained by subtracting 1 from m raised to the (l−1) power. In FIG. 2, there are four candidates for the state of the transmission signal at time n, and R=3. Specifically, the state of the transmission signal at time n is the symbol of the transmission signal at time n. Note that the symbol of the transmission signal at time n means the nth symbol in the transmission signal. In FIG. 2, the four states are expressed as S₀, S₁, S₂, and S₃.

State S₀ is a symbol expressed by an ordered set of “0” bits and “0” bits. State S₁ is a symbol expressed by an ordered set of “0” bits and “1” bits. State S₂ is a symbol expressed by an ordered set of “1” bits and “0” bits. State S₃ is a symbol expressed by an ordered set of “1” bits and “1” bits.

p^{M}ₙ₊₁ (M is an integer from 0 to R) is a quantity called a path metric in the Viterbi algorithm. Therefore, the path metric p^{M}ₙ₊₁ is a distance that is obtained by the Viterbi algorithm, is indicated by a predetermined distance function, and indicates a likelihood that the symbol of the transmission signal at time (n+1) is Sᵣ. The path metric p^{M}ₙ₊₁ may be the sum of the distance indicating the likelihood that the symbol of the transmission signal at time (n+1) is Sᵣ and the distance of the first to nth remaining paths of the transmission signal. Note that the distance of the predetermined distance function may be, for example, a squared error or a sum of squared errors.

b^{q}ₙ₊₁ (q is an integer from 1 to Q; Q=(R+1)×m) is a quantity called a branch metric in the Viterbi algorithm. Therefore, the branch metric b^{q}ₙ₊₁ is a distance that is obtained by the Viterbi algorithm, is indicated by a predetermined distance function, and indicates a likelihood of transition from the nth symbol of the transmission signal to each candidate for the (n+1)th symbol. Since the symbol multilevel degree is m=2, the next bit of the (n+1)th symbol following each candidate for the nth symbol is either 0 or 1. Therefore, the number Q of branch metrics is (R+1)×m.

The distance indicated by the branch metric may be, for example, a squared error or the sum of squared errors. The distance of the predetermined distance function in the path metric may be different from the distance of the predetermined distance function in the branch metric. Therefore, for example, when the distance indicated by the branch metric is a squared error, the distance indicated by the path metric is the sum of squared errors.

In the example of FIG. 2, for example, when the symbol at time (n−1) is in state S₀, the distance indicated by the branch metric when it becomes state S₁ at time n is bin.

The value of the branch metric is calculated based on the estimated transfer function, which is a previously obtained estimation result of the transfer function of the transmission line 2, and the received signal. The estimated transfer function is estimated, for example, based on the result of propagating a training signal prepared in advance to the receiver 3 via the transmission line 2.

The process of calculating the branch metric value based on the estimated transfer function and the received signal may be any existing process. The process of calculating the value of the branch metric based on the estimated transfer function and the received signal is, for example, a process of obtaining the squared error between the received signal and the result of applying an estimated transfer function to the symbol sequence indicated by the branch metric. Note that the symbol sequence indicated by the branch metric means a candidate sequence corresponding to the branch corresponding to the branch metric.

The (n+1)th path metric is the sum of the nth path metric of the transition source and the branch metric indicating the likelihood of transition from the nth state of the transition source to the (n+1)th state of the transition destination.

The Viterbi algorithm is a process of sequentially calculating path metrics and branch metrics from time n=1 to n=N in this way.

### <First Soft Decision Process>

The description will now return to FIG. 1. The control unit 40 performs, for example, a first soft decision process as a process of performing a soft decision on the (n+1)th (n is an integer from 1 to N, N is an integer of 1 or more) symbol of the transmission signal. The first soft decision process is a process including a branch metric estimation process, a path metric estimation process, and a bit likelihood estimation process.

The branch metric estimation process is a process of estimating the likelihood of transition from the nth symbol of the transmission signal to each candidate for the (n+1)th symbol, which is the likelihood obtained by the Viterbi algorithm, based on the received signal and the estimated transfer function, which is a previously obtained estimation result of the transfer function of the transmission line 2. As described above, the likelihood of transition from the nth symbol of the transmission signal to each candidate for the (n+1)th symbol is a quantity called a branch metric in the Viterbi algorithm. Therefore, states S₀, S₁, S₂, and S₃ in the example of FIG. 2 are examples of candidates.

The path metric estimation process is a process of estimating the likelihood that each candidate for the (n+1)th symbol of the transmission signal is a symbol of the transmission signal, which is the likelihood obtained by the Viterbi algorithm, based on the result of the branch metric estimation process. As described above, the likelihood that each candidate for the (n+1)th symbol of the transmission signal is a symbol of the transmission signal, which is the likelihood obtained by the Viterbi algorithm, is a quantity called the path metric in the Viterbi algorithm.

The bit likelihood estimation process is a process of estimating the likelihood that the kth bit (k is an integer from 1 to m) in the (n+1)th symbol of the transmission signal is a predetermined bit using the path metric of each candidate for the (n+1)th symbol of the transmission signal. The path metric of each candidate for the (n+1)th symbol of the transmission signal is a path metric obtained by path metric estimation process. The bit likelihood estimation process is a process that does not use path metrics other than the path metric of each candidate for the (n+1)th symbol of the transmission signal.

The control unit 40 acquires the likelihood estimated by the bit likelihood estimation process as a soft decision result for the (n+1)th symbol of the transmission signal.

### First Example of Likelihood in First Soft Decision Process

The likelihood estimated by the bit likelihood estimation process is expressed, for example, by the following Equation (1). The left side λ_{k,n} of Equation (1) is the likelihood estimated by a bit likelihood estimation process, and indicates the likelihood that the kth bit of the nth symbol of the transmission signal is 0. Note that in the example of Equation (1), there are two types of bits: 0 and 1. Therefore, information indicating the likelihood that the bit is 0 is also information indicating the likelihood that the bit is 1.

$$\begin{matrix}[ Math . 1 ] & \\ {λ}_{k , n} = \frac{1}{2 {σ}^{2}} [ min \{ {L}_{M , n} \vert {c}_{k , n} ∈ {u}_{M} , {c}_{k , n} = 0 \} - min \{ {L}_{M , n} \vert {c}_{k , n} ∈ {u}_{M} , {c}_{k , n} = 1 \} ] & ( 1 )\end{matrix}$$

$$\begin{matrix}[ Math . 2 ] & \\ {L}_{M , n} = min \{ {p}_{n}^{j} \vert j ∈ Z , j < {m}^{l - 1} , mod ( j , m ) = M \} & ( 2 )\end{matrix}$$

c_{k,n} represents the kth bit of the nth symbol of the transmission signal. σ represents the standard deviation of the distribution of noise added to the optical signal in the transmission line 2. Therefore, when the likelihood estimated by the bit likelihood estimation process is expressed by Equation (1), in the bit likelihood estimation process, information indicating the standard deviation of the distribution of noise added to the optical signal in the transmission line 2 is also used.

The standard deviation of the distribution of noise added to the optical signal on the transmission line 2 is, for example, a predetermined value. Note that u_{M} represents a symbol value candidate. That is, u_{M} represents each symbol value of u₀ to u_{R}. Therefore, for example, in a case where a modulation scheme is PAM4, for example, u_{M} represents u₀=[c_{1,n}, c_{2,n}]=[0, 0] if M=0, represents u₁=[c_{1,n}, c_{2,n}]=[0, 1] if M=1, represents u₂=[c_{1,n}, c_{2,n}]=[1, 1] if M=2, and represents u₃=[c_{1,n}, c_{2,n}]=[1, 0] if M=3.

### Second Example of Likelihood in First Soft Decision Process

The likelihood estimated by the bit likelihood estimation process may be expressed, for example, by the following Equation (3). Note that Equation (1) is an approximate equation of Equation (3). Specifically, the content of the approximation is an approximation in which symbols other than the maximum symbol likelihood are replaced with 0.

The left side λ_{k,n} of Equation (3) is the likelihood estimated by a bit likelihood estimation process, and indicates the likelihood that the kth bit of the nth symbol of the transmission signal is 0. Note that in the example of Equation (3), there are two types of bits: 0 and 1. Therefore, information indicating the likelihood that the bit is 0 is also information indicating the likelihood that the bit is 1.

$$\begin{matrix}[ Math . 3 ] & \\ {λ}_{k , n} = ln \frac{{\sum }_{M = 1}^{m} \{ {L}_{M , n} \vert {c}_{k , n} ∈ {u}_{M} , {c}_{k , n} = 1 \}}{{\sum }_{M = 1}^{m} \{ {L}_{M , n} \vert {c}_{k , n} ∈ {u}_{M} , {c}_{k , n} = 0 \}} & ( 3 )\end{matrix}$$

$$\begin{matrix}[ Math . 4 ] & \\ {L}_{M , n} = {\prod }_{j = 1}^{{m}^{l - 1} - 1} \{ \frac{1}{\sqrt{2 {πσ}^{2}}} {e}^{- \frac{{p}_{n}^{j}}{2 {σ}^{2}}} \vert mod ( j , m ) = M \} & ( 4 )\end{matrix}$$

Equation (4) includes the value of the standard deviation of the distribution of noise added to the optical signal in the transmission line 2. Therefore, when the likelihood estimated by the bit likelihood estimation process is expressed by Equation (3), in the bit likelihood estimation process, information indicating the standard deviation of the distribution of noise added to the optical signal in the transmission line 2 is also used.

### <Second Soft Decision Process>

The control unit 40 may perform, for example, a second soft decision process as a process of performing a soft decision on the (n+1)th (n is an integer from 1 to N, N is an integer of 1 or more) symbol of the transmission signal. The second soft decision process includes a hard decision process, a likelihood estimation process, and a difference acquisition process.

The hard decision process is a process of performing a hard decision using the Viterbi algorithm based on the estimated transfer function and the received signal.

The likelihood estimation process is a process of estimating the likelihood of each candidate for the (n+1)th symbol (hereinafter referred to as a “symbol candidate”) of the transmission signal based on the result of the hard decision process, the estimated transfer function, and the received signal. States S₀, S₁, S₂, and S₃ in the example of FIG. 2 are examples of symbol candidates. The likelihood estimated by the likelihood estimation process is called an estimated likelihood.

The difference acquisition process is a process of acquiring a difference between an estimated likelihood of a symbol candidate whose kth bit (k is an integer from 1 to K) is a predetermined bit among symbol candidates and an estimated likelihood of a symbol candidate whose kth bit is not a predetermined bit among the symbol candidates (hereinafter referred to as a “likelihood difference”).

The control unit 40 acquires the likelihood difference obtained in the difference acquisition process as a soft decision result for the (n+1)th symbol of the transmission signal.

### First Example of Estimated Likelihood in Second Soft Decision Process

The estimated likelihood is expressed, for example, by the following Equation (5).

$$\begin{matrix}[ Math . 5 ] & \\ {L}_{M , n} = {( {C}_{M , n}^{′} \cdot \hat{H} - {y}_{n} )}^{2} & ( 5 )\end{matrix}$$

$$\begin{matrix}[ Math . 6 ] & \\ {C}_{M , n}^{′} = \{ {x}_{n - l + 1}^{′} , … , {x}_{n - 1}^{′} , {u}_{M} \} & ( 6 )\end{matrix}$$

In Equation (5), H with a hat (\hat{ }) as an accent symbol represents an estimated transfer function. yₙ represents a received signal. C′_{M,n} expressed in Equation (6) represents an ordered set of the result of the hard decision process and the symbol u_{M}, which is one of the candidates for the nth symbol of the transmission signal. Hereinafter, the ordered set C′_{M,n} will be referred to as a target ordered set. x′ₙ represents the nth symbol of the transmission signal estimated by a hard decision process. Note that l is the storage length as described above.

When the estimated likelihood is expressed by Equation (5), the likelihood difference is expressed, for example, by the following Equation (7). Note that in the example of Equation (7), there are two types of bits: 0 and 1. Therefore, information indicating the likelihood that the bit is 0 is also information indicating the likelihood that the bit is 1.

$$\begin{matrix}[ Math . 7 ] & \\ {λ}_{k , n} = \frac{1}{2 {σ}^{2}} [ min \{ {L}_{M , n} \vert {c}_{k , n} ∈ {u}_{M} , {c}_{k , n} = 0 \} - min \{ {L}_{M , n} \vert {c}_{k , n} ∈ {u}_{M} , {c}_{k , n} = 1 \} ] & ( 7 )\end{matrix}$$

Equation (7) includes the value of the standard deviation of the distribution of noise added to the optical signal in the transmission line 2. Therefore, when the likelihood difference estimated by the difference acquisition process is expressed by Equation (7), in the difference acquisition process, information indicating the standard deviation of the distribution of noise added to the optical signal in the transmission line 2 is also used.

### Second Example of Estimated Likelihood in Second Soft Decision Process

The estimated likelihood may be expressed, for example, by the following Equation (8). Note that Equation (5) is obtained by normalizing Equation (8) and taking the natural logarithm. Here, coefficients that do not depend on M and n are normalized.

$$\begin{matrix}[ Math . 8 ] & \\ {L}_{M , n} = \frac{1}{\sqrt{2 π {σ}^{2}}} {e}^{- \frac{{( C {′}_{M , n} \cdot \hat{H} - {y}_{n} )}^{2}}{2 {σ}^{2}}} & ( 8 )\end{matrix}$$

Equation (8) includes the value of the standard deviation of the distribution of noise added to the optical signal in the transmission line 2. Therefore, when the likelihood estimated by the likelihood estimation process is expressed by Equation (8), in the likelihood estimation process, information indicating the standard deviation of the distribution of noise added to the optical signal in the transmission line 2 is also used.

When the estimated likelihood is expressed by Equation (8), the likelihood difference is expressed, for example, by the following Equation (9). Note that in the example of Equation (9), there are two types of bits: 0 and 1. Therefore, information indicating the likelihood that the bit is 0 is also information indicating the likelihood that the bit is 1.

$$\begin{matrix}[ Math . 9 ] & \\ {λ}_{k , n} = ln \frac{{\sum }_{M = 1}^{m} \{ {L}_{m , n} \vert {c}_{k , n} ∈ {u}_{M} , {c}_{k , n} = 1 \}}{{\sum }_{M = 1}^{m} \{ {L}_{m , n} \vert {c}_{k , n} ∈ {u}_{M} , {c}_{k , n} = 0 \}} & ( 9 )\end{matrix}$$

### Third Example of Estimated Likelihood in Second Soft Decision Process

The estimated likelihood may be obtained, for example, based on the difference between the received signal and the result of applying the estimated transfer function to the result of the hard decision process. The difference between the received signal and the result of applying the estimated transfer function to the result of the hard decision process represents the result of estimating the noise distribution.

Specifically, the difference between the received signal and the result of applying the estimated transfer function to the result of the hard decision process is expressed by the following Equation (10).

$$\begin{matrix}[ Math . 10 ] & \\ W = {x}_{n}^{′} \cdot \hat{H} - {y}_{n} & ( 10 )\end{matrix}$$

In Equation (10), x′ₙ expressed in bold refers to the ordered set of the following Equation (11).

$$\begin{matrix}[ Math . 11 ] & \\ \{ {x}_{n - l + 1}^{′} , … , {x}_{n - 1}^{′} \} & ( 11 )\end{matrix}$$

As described above, since the distribution of the difference between the received signal and the result of applying the estimated transfer function to the result of the hard decision process is the result of estimating the noise distribution, W is a quantity representing the result of estimating the noise.

Hereinafter, a process of obtaining an estimated likelihood of a candidate for the (n+1)th symbol of the transmission signal based on the distribution of the difference between the received signal and the result of applying the estimated transfer function to the result of the hard decision process is called a modified likelihood estimation process. Since the modified likelihood estimation process is a process of estimating the likelihood of each candidate for the (n+1)th symbol of the transmission signal based on the result of the hard decision process, the estimated transfer function, and the received signal, it is a type of likelihood estimation process.

Note that, as can be seen from Equation (11), the result of the hard decision process used in the modified likelihood estimation process is the result of the hard decision process for l symbols before the estimation target in the modified likelihood estimation process. Therefore, for example, when a candidate for the (n+1)th symbol of the transmission signal is an estimation target by the modified likelihood estimation process, hard decisions are performed on l symbols before the nth symbol in the hard decision process.

In the modified likelihood estimation process, for example, a histogram of a predetermined class width is generated for the noise W with the number of samples a. The horizontal axis of the histogram represents class, and the vertical axis represents frequency. Note that the process for noise with the number of samples a means the process for a set whose element is noise W and whose number of elements is a. In such a case, in the modified likelihood estimation process, next, the number of samples in each class is then normalized by the number of samples in the class with the largest number of samples.

In such a case, in the modified likelihood estimation process, next, the number of normalized samples belonging to the class that includes the difference between the received signal and the result of applying the estimated transfer function to the target ordered set C′_{M,n} is acquired as the likelihood for each symbol. Note that the meaning “includes the difference between the received signal and the result of applying the estimated transfer function to the target ordered set C′_{M,n}” specifically means that a class corresponding to the likelihood of symbol M at time index n is selected.

### <Hardware Description>

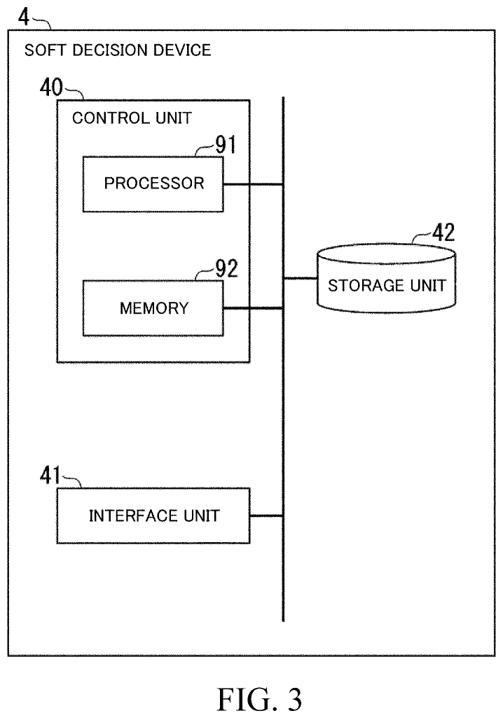

FIG. 3 is a diagram showing an example of a hardware configuration of the soft decision device 4 according to the embodiment. The soft decision device 4 includes a control unit 40 including a processor 91 such as a CPU and a memory 92, which are connected by a bus, and executes a program. The soft decision device 4 functions as a device including a control unit 40, an interface unit 41, and a storage unit 42 by executing a program.

More specifically, the processor 91 reads the program stored in the storage unit 42, and stores the read program in the memory 92. When the processor 91 executes the program stored in the memory 92, the soft decision device 4 functions as a device including the control unit 40, the interface unit 41, and the storage unit 42.

The control unit 40 controls operations of various functional units provided in the soft decision device 4. The control unit 40 executes, for example, a first soft decision process. The control unit 40 executes, for example, a second soft decision process instead of the first soft decision process.

The interface unit 41 includes an interface for connecting the soft decision device 4 to an external device. The interface unit 41 communicates with an external device via wired or wireless. The external device is, for example, the receiver 3. In such a case, the interface unit 41 acquires the received signal acquired by the receiver 3, for example.

The interface unit 41 includes, for example, input devices such as a mouse, a keyboard, and a touch panel. The interface unit 41 may include an interface for connecting these input devices to the soft decision device 4.

The interface unit 41 includes, for example, display devices such as a cathode ray tube (CRT) display, a liquid crystal display, or an electro-luminescence (EL) display. The interface unit 41 may include an interface for connecting these display devices to the soft decision device 4.

The storage unit 42 is configured using a non-transitory computer-readable recording medium such as a magnetic hard disk device or a semiconductor storage device. The storage unit 42 stores various types of information regarding the soft decision device 4. The storage unit 42 may store various types of information generated as a result of processing executed by the control unit 40, for example. The storage unit 42 may store, for example, the received signal acquired by the interface unit 41. The storage unit 42 may store the estimated transfer function in advance, for example.

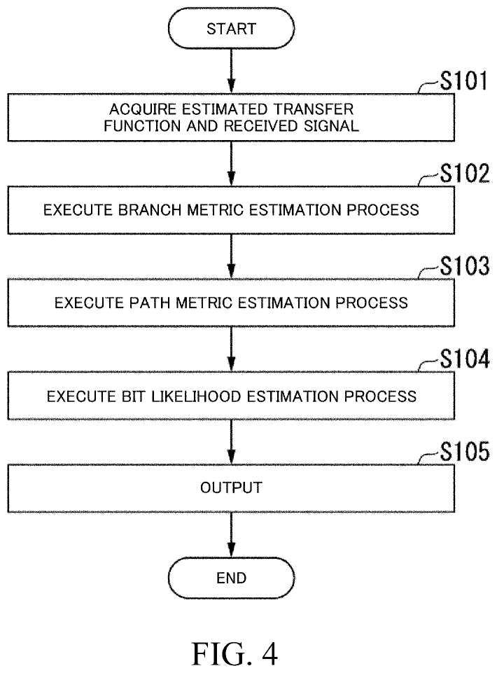

FIG. 4 is a flowchart showing a first example of a flow of processing executed by the soft decision device 4 according to the embodiment. More specifically, FIG. 4 is a flowchart showing an example of a flow of processing executed by the soft decision device 4 that executes a first soft decision process.

The control unit 40 acquires the estimated transfer function stored in the storage unit 42 and the received signal acquired by the interface unit 41 (step S101). Next, the control unit 40 executes a branch metric estimation process (step S102). Next, the control unit 40 executes a path metric estimation process (step S103).

Next, the control unit 40 executes a bit likelihood estimation process (step S104). The control unit 40 acquires the likelihood estimated in the process of step S104 as a soft decision result for the (n+1)th symbol of the transmission signal. Next, the control unit 40 controls the operation of the interface unit 41 to output the likelihood estimated in step S104 to the interface unit 41 (step S105).

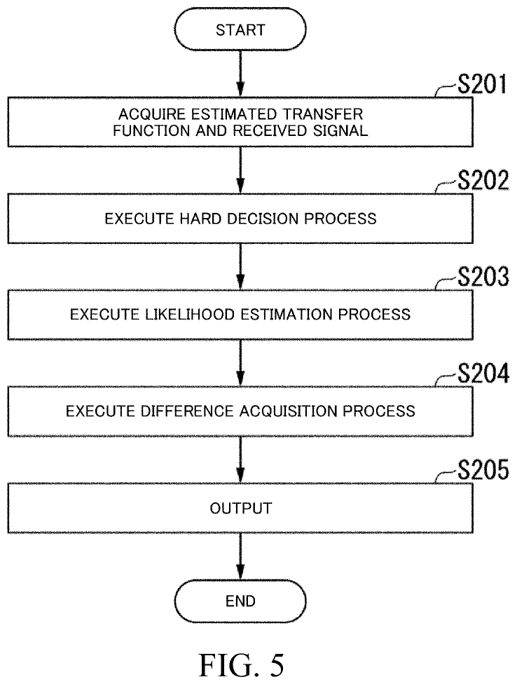

FIG. 5 is a flowchart showing a second example of a flow of processing executed by the soft decision device 4 according to the embodiment. More specifically, FIG. 5 is a flowchart showing an example of a flow of processing executed by the soft decision device 4 that executes a second soft decision process.

The control unit 40 acquires the estimated transfer function stored in the storage unit 42 and the received signal acquired by the interface unit 41 (step S201). Next, the control unit 40 executes a hard decision process (step S202). Next, the control unit 40 executes a likelihood estimation process (step S203).

Next, the control unit 40 executes a difference acquisition process (step S204). The control unit 40 acquires the likelihood difference acquired in the process of step S204 as a soft decision result for the (n+1)th symbol of the transmission signal. Next, the control unit 40 controls the operation of the interface unit 41 to output the likelihood difference estimated in step S204 to the interface unit 41 (step S205).

In this way, the soft decision device 4 that executes the second soft decision process performs a soft decision on the main symbol, which is the (n+1)th symbol of the transmission signal with a symbol multilevel degree of m. The soft decision device 4 that executes the second soft decision process includes the control unit 40. The control unit 40 executes a hard decision process that performs a hard decision using the Viterbi algorithm based on an estimated transfer function that is a previously obtained estimation result of the transfer function of the transmission line 2 through which the transmission signal propagates and a received signal that is a result of reception of the transmission signal. The control unit 40 executes a likelihood estimation process of of estimating the likelihood of each candidate for the (n+1)th symbol of the transmission signal based on the result of the hard decision process, the estimated transfer function, and the received signal. The control unit 40 executes a difference acquisition process of acquiring a difference between a likelihood of a candidate whose kth bit (k is an integer from 1 to m) is a predetermined bit among candidates and a likelihood of a candidate whose kth bit is not a predetermined bit among the candidates. The control unit 40 outputs the acquired difference as a soft decision result.

### <Experimental Results>

An example of results of an experiment using the soft decision device 4 will be described. In the experiment, a comparative experiment was also conducted to evaluate the effectiveness of the experiment using the soft decision device 4. The technology used in the comparative experiment was a technology that did not use the soft decision device 4 (hereinafter referred to as “comparative technology”). More specifically, the comparative technology is a technology that estimates the main symbol by applying an inverse function of the transfer function to the received signal.

First, an example of the optical transmission system 100 used in the experiment will be described.

In the experiment, the transmitter 1 converted a digital signal indicating the content that the user wanted to transmit into an analog signal. The conversion in the experiment was performed at 128 Gsample/s and 65 GHz. In the experiment, in the transmitter 1, the analog signal obtained by conversion was amplified by an amplifier.

In the experiment, the transmitter 1 modulated a laser beam with a wavelength of 1310 nm using an amplified analog signal and outputted the result as an optical signal. The modulation scheme was PAM4. The optical signal output from the transmitter 1 entered the transmission line 2 and propagated through the transmission line 2.

In the experiment, the transmission line 2 was a single mode fiber with a length of 10 km. The wavelength dispersion of the transmission line 2 was −8 ps/nm at a wavelength of 1310 nm.

In the experiment, the receiver 3 was equipped with a variable optical attenuator, and in the receiver 3, the power of the optical signal emitted from the transmission line 2 was attenuated by the variable optical attenuator. The receiver 3 used a photodiode to convert the optical signal whose power was attenuated by the variable optical attenuator into an electrical signal. The photodiode bandwidth was 50 GHz.

In the receiver 3, the electrical signal obtained by the photodiode was amplified and then converted into a digital signal. Conversion to a digital signal was performed at 160 Gsample/s and 63 GHz. The converted signal is an example of a received signal, and was an example of a received signal in the experiment.

In the experiment, the soft decision device 4 acquired the received signal obtained in this manner. In the experiment, the control unit 40 included in the soft decision device 4 executed the first soft decision process and acquired the likelihood estimated by the first soft decision process as the result of the soft decision. More specifically, in the experiment, the control unit 40 estimated the likelihood expressed by Equation (1) by executing the first soft decision process.

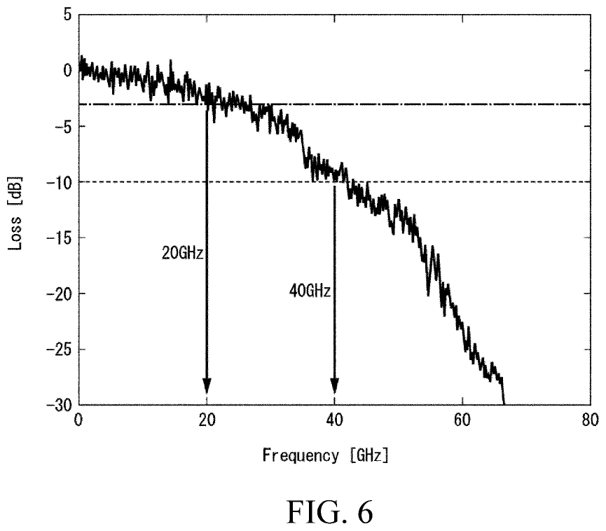

FIG. 6 is a first diagram showing an example of experimental results in the embodiment. More specifically, FIG. 6 is a diagram showing an example of experimental results using the comparative technology. The horizontal axis in FIG. 6 indicates frequency. The vertical axis in FIG. 6 indicates loss. FIG. 6 shows that when the comparative technology is used, the loss becomes large near a frequency of 60 GHz.

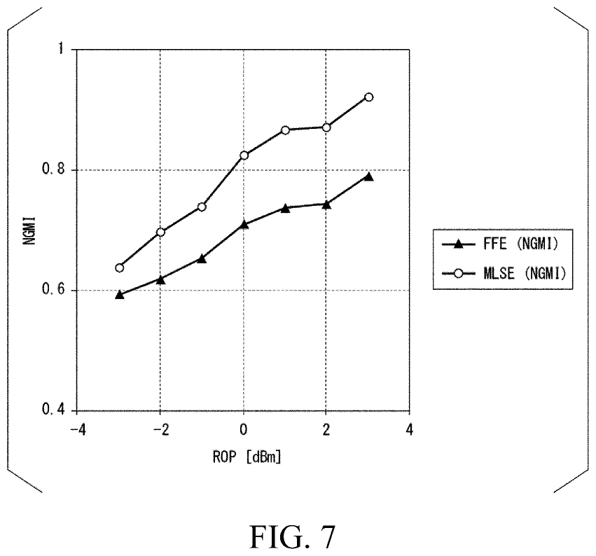

FIG. 7 is a second diagram showing an example of experimental results in the embodiment. The horizontal axis in FIG. 7 indicates received optical power (ROP). The vertical axis in FIG. 7 indicates normalized general mutual information (NGMI).

“Maximum likelihood sequence estimation (MLSE (NGMI))” executes the first soft decision process using the soft decision device 4 and estimates the likelihood expressed by Equation (1), and the result is indicated as a value of NGMI. “Feed-forward equalizer (FFE (NGMI))” indicates the result using the comparative technology as a value of NGMI. FIG. 7 means that the NGMI is higher when the first soft decision process is executed using the soft decision device 4 and the likelihood expressed by Equation (1) is estimated than when using the comparative technology.

FIG. 7 shows that by using the results of the soft decision made by the soft decision device 4, the main symbol can be estimated with higher accuracy than the comparative technology.

### <Description of Effects of Soft Decision Device 4>

As described above, the comparative technology estimates the main symbol by applying an inverse function of the transfer function to the received signal. When the inverse function is applied, even the noise added to the signal in the transmission line 2 is amplified. On the other hand, since the soft decision device 4 does not use the inverse function of the transfer function, noise will not be amplified. Therefore, the soft decision device 4 can estimate the main symbol with higher accuracy than the comparative technology.

The soft decision device 4 configured in this manner executes the first soft decision process or the second soft decision process. Therefore, since the soft decision result is obtained without using the inverse function of the transfer function, the soft decision device 4 can estimate the symbol of the transmission signal with higher accuracy.

### Modification Example of First Embodiment

Note that the above Equations (1), (4), (7), and (8) include the standard deviation σ of the distribution of noise added to the optical signal in the transmission line 2, but the value of the standard deviation σ of the distribution of noise added to the optical signal in the transmission line 2 may be a predetermined value, or may not be a predetermined value.

For example, the value of the standard deviation σ may be obtained based on the difference between the received signal and the result of applying the estimated transfer function to the correct data. The correct data is data indicating the correct answer of the transmission signal. Therefore, for example, the standard deviation σ may be obtained by the process expressed by the following Equation (12).

$$\begin{matrix}[ Math . 12 ] & \\ σ = {\{ \frac{1}{D} {\sum }_{d = e}^{e + D - 1} {( {C}_{d} \cdot \hat{H} - {y}_{d} )}^{2} \}}^{1 / 2} & ( 12 )\end{matrix}$$

$$\begin{matrix}[ Math . 13 ] & \\ {C}_{d} = \{ {x}_{d - l + 1} , … , {x}_{d} \} & ( 13 )\end{matrix}$$

x_{d} in Equation (13) indicates the dth symbol of the transmission signal indicated by the correct data. l in Equation (13) means the storage length of the estimated transfer function, while e in Equation (12) indicates the start position of the transmission signal indicated by the correct data. The start position indicates the position in the time axis direction in the correct data to be used. D represents the number of symbols used to calculate the standard deviation σ. d means the time index in the correct data to be used. Therefore, Equation (12) represents the process of acquiring the average value of D estimated noises as the standard deviation σ. The estimation noise is the squared error between the received signal and the result of applying the estimated transfer function to the correct data.

For example, the value of the standard deviation σ may be obtained based on the difference between the received signal and the result of applying the estimated transfer function to the result of the hard decision process. Therefore, for example, the standard deviation σ may be obtained by the process expressed by the following Equation (14).

$$\begin{matrix}[ Math . 14 ] & \\ σ = {\{ \frac{1}{D} {\sum }_{d = e}^{e + D - 1} {( {C}_{d}^{′} \cdot \hat{H} - {y}_{d} )}^{2} \}}^{1 / 2} & ( 14 )\end{matrix}$$

$$\begin{matrix}[ Math . 15 ] & \\ {C}_{d}^{′} = \{ {x}_{d - l + 1}^{′} , … , {x}_{d}^{′} \} & ( 15 )\end{matrix}$$

x′_{d} in Equation (15) indicates the dth symbol of the transmission signal indicated by the result of the hard decision process. l in Equation (15) means the storage length of the estimated transfer function, while e in Equation (14) indicates the start position of the transmission signal indicated by the result of the hard decision process. The start position indicates the position in the time axis direction in the result of the hard decision process. D represents the number of symbols used to calculate the standard deviation σ. d means the time index in the hard decision result to be used. Therefore, Equation (14) represents the process of acquiring the average value of D estimated noises as the standard deviation σ.

For example, the value of the standard deviation σ may be a value that satisfies the condition of maximizing the NGMI. NGMI is, for example, a quantity defined by the following Equation (16).

$$\begin{matrix}[ Math . 16 ] & \\ NGMI \frac{GMI}{{m}^{′}} & ( 16 )\end{matrix}$$

$$\begin{matrix}[ Math . 17 ] & \\ CrossEntropy = \frac{1}{N} {\sum }_{k = 1}^{m} {\sum }_{n = 1}^{N} {log}_{2} ( 1 + exp [ {( - 1 )}^{{c}_{k , n}} \times {λ}_{k , n} ] ) & ( 17 )\end{matrix}$$

$$\begin{matrix}[ Math . 18 ] & \\ GMI {m}^{′} - CrossEntropy & ( 18 )\end{matrix}$$

m′ represents the number of transmission signal bits. Therefore, m′ is log₂m′=2 when the modulation scheme is PAM4, for example. N represents the number of symbols used to calculate CrossEntropy.

Note that the value of the soft output (that is, the result of the soft decision) may diverge to the plus side or the minus side. Some programming languages do not produce a value when they diverge. Therefore, in order to avoid a situation where no value is obtained, in the process of performing a soft decision on the (n+1)th symbol of the transmission signal, an upper or lower limit of the soft output value may be determined in advance.

Note that the soft decision device 4 may be implemented by using a plurality of information processing devices that are communicatively connected via a network. In this case, each functional unit provided in the soft decision device 4 may be distributed and mounted in a plurality of information processing devices.

Note that all or some of the functions of the soft decision device 4 may be realized using hardware such as an application specific integrated circuit (ASIC), a programmable logic device (PLD), or a field programmable gate array (FPGA). The program may be recorded on a computer-readable recording medium. The computer-readable recording medium is, for example, a portable medium such as a flexible disk, a magneto-optical disk, a ROM, or a CD-ROM, or a storage device such as a hard disk built in a computer system. The program may be transmitted over telecommunication lines.

### Second Embodiment

In a second embodiment, when a symbol determination result (hard decision result) obtained by backward calculation (tracing back remaining paths) in a trellis diagram is different from a symbol determination result obtained by forward calculation (path metric calculation and remaining path selection), the main difference from the first embodiment is that the soft decision result obtained by backward calculation for complex soft decision output, which also requires path metrics indicated by paths other than the remaining paths, is replaced with a predetermined soft decision result obtained by simple calculation. The second embodiment will be described with a focus on the differences from the first embodiment.

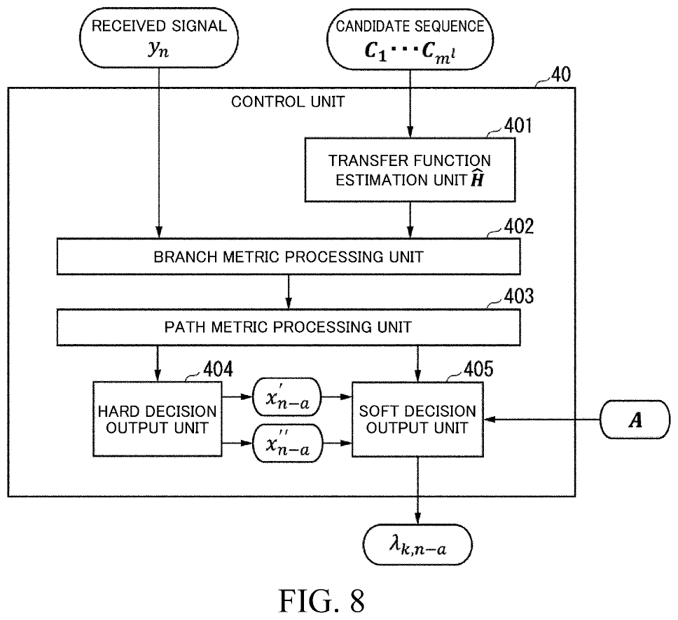

FIG. 8 is a diagram showing an example of a configuration of a control unit 40 according to the embodiment. The control unit 40 includes a transfer function estimation unit 401, a branch metric processing unit 402, a path metric processing unit 403, a hard decision output unit 404, and a soft decision output unit 405.

In the following, symbols added above characters in mathematical formulas or functions (hereinafter referred to as “mathematical formulas or the like”) are written before the characters. For example, the symbol “\hat{ }” added above a character in a mathematical formula or the like will be written as “\hat{ }H” before the character “H” below.

The transfer function estimation unit 401 calculates the estimated transfer function “\hat{ }H” as shown in Equation (19).

$$\begin{matrix}[ Math . 19 ] & \\ \hat{H} = \{ , … , \} & ( 19 )\end{matrix}$$

The branch metric processing unit 402 calculates the branch metric “b” as shown in Equation (20).

$$\begin{matrix}[ Math . 20 ] & \\ {b}_{n}^{i} = {( {C}_{i} \cdot \hat{H} - {y}_{n} )}^{2} , \{ i \vert i ∈ Z , i < {m}^{l} \} & ( 20 )\end{matrix}$$

The path metric processing unit 403 calculates the path metric “p” as shown in Equation (21).

$$\begin{matrix}[ Math . 21 ] & \\ {p}_{n}^{j} = min \{ {p}_{n - 1}^{q} + {b}_{n}^{d} \vert j ∈ Z , j < {m}^{l - 1} , mod ( d , {m}^{l - 1} ) = j , q = ⌊ \frac{d}{m} ⌋ \} & ( 21 )\end{matrix}$$

The hard decision output unit 404 compares the path metric “p” of each state “s” for each time index. The hard decision output unit 404 selects the minimum path metric from among the path metrics of the “m^{l}” states “s” at the time index “n” based on the comparison result of the path metrics “p.” The path in the time direction made up of the branches used to calculate the selected minimum path metric is called a “remaining path.”

No matter which state “s” is selected as the starting point for tracing back the remaining path of the trellis diagram in the direction opposite to the time direction (state transition direction), the same path will be traced back. Tracing back the same path is called “merging paths by backward calculation.” A symbol corresponding to the state after tracing back the merged path (hereinafter referred to as “retrace destination”) is output as a symbol determination result. The symbol determination result corresponds to a hard decision result (hard decision output).

The hard decision output unit 404 generates a hard decision result “x′ₙ₋ₐ” by backward calculation in the trellis diagram. The symbol determination result is expressed as in Equation (22).

$$\begin{matrix}[ Math . 22 ] & \\ {x}_{n - a}^{′} = {u}_{mod ( j , m )} & ( 22 )\end{matrix}$$

Here, “a” represents the number of times the path is traced back in the direction opposite to the state transition direction (number of tracebacks). “sⱼ” represents the state at the retrace destination “j.”

Further, the hard decision output unit 404 generates a hard decision result “x″ₙ₋ₐ” by forward calculation in the trellis diagram. When the state with the minimum path metric at the time index “n” is “sⱼ,” the symbol “x″ₙ” determined as a result of the forward calculation (path metric calculation and remaining path selection) is expressed as in Equation (23). Note that the time index of state Sⱼ in Equation (23) is different from the time index of state Sⱼ in Equation (22). Therefore, it should be noted that the left side of Equation (23) and the left side of Equation (22) are not in an equal relationship.

$$\begin{matrix}[ Math . 23 ] & \\ {x}_{n}^{″} = {u}_{mod ( j , m )} & ( 23 )\end{matrix}$$

This determined symbol “x″ₙ” is a determination result obtained by using only forward calculations (path metric calculation and remaining path selection) without using backward calculations (tracing back the remaining paths). Here, since only sequence estimation of the sequence length of the most likely symbol candidate is possible, the effect of sequence estimation of the sequence length including the number of tracebacks by backward calculation cannot be obtained.

Therefore, even for the same time index “n−a,” the symbol determination result “x′ₙ₋ₐ” by backward calculation may be different from the symbol determination result “x″ₙ₋ₐ” by forward calculation. In addition, when they are different, the symbol determination result “x′ₙ₋ₐ” by backward calculation is more likely to be accurate than the symbol determination result “x″ₙ₋ₐ” by forward calculation.

In Equation (1) exemplified in the first embodiment, a log likelihood ratio “λ_{M,n}” is calculated based on path metric information obtained by forward calculation. Therefore, when the symbol determination result “x′ₙ₋ₐ” of the backward calculation is different from the symbol determination result “x″ₙ₋ₐ” of the forward calculation, there is a possibility that the accuracy of the log likelihood ratio “λ” estimated based on path metric information obtained by forward calculation is not high.

Therefore, in the second embodiment, the soft decision output unit 405 approximately incorporates the effect of path tracing back (backward calculation) in the trellis diagram through simple calculation. That is, the soft decision output unit 405 replaces the soft decision result of complicated backward calculation with the soft decision result of simple calculation. The complexity of this simple calculation is, for example, comparable to the complexity of the Viterbi algorithm used in hard-decision maximum likelihood sequence estimation (MLSE).

The log likelihood ratio “λ′_{k,n}” is expressed as in Equation (24) using Equation (25). The calculation of Equation (24) is essentially the same as Equation (7).

$$\begin{matrix}[ Math . 24 ] & \\ {λ}_{k , n}^{′} = \frac{1}{2 {σ}^{2}} [ min \{ {L}_{M , n} \vert {c}_{k , n}^{′} ∈ {u}_{M} , {c}_{k , n}^{′} = 0 \} - min \{ {L}_{M , n} \vert {c}_{k , n}^{′} ∈ {u}_{M} , {c}_{k , n}^{′} = 1 \} ] & ( 24 )\end{matrix}$$

$$\begin{matrix}[ Math . 25 ] & \\ {L}_{M , n} = min \{ {p}_{n}^{j} \vert j ∈ Z , j < {m}^{l - 1} , mod ( j , m ) = M \} & ( 25 )\end{matrix}$$

Here, “n” represents a time index (1≤n≤N). “k” represents the number (1≤k≤m) of the bit in the symbol determination result at the time index “n.” “c′_{k,n}” represents the kth bit (0 or 1) of the symbol determination result “x′ₙ” at the time index “n.” Note that “c″_{k,n}” represents the kth bit (0 or 1) of the symbol determination result “x″ₙ” at the time index “n.”

The soft decision output unit 405 acquires a predetermined positive constant “A” from the memory 92, for example. This constant “A” is determined in advance, for example, so that the normalized general mutual information (NGMI) is maximized according to the result of changing the positive variable at predetermined intervals. For example, by changing a variable that takes a value from 0.001 to 1.000 at intervals of 0.001, a log likelihood ratio “λ” is calculated for each value of the variable. The value of the variable when the normalized general mutual information is maximized is determined in advance as a positive constant “A.”

The soft decision output unit 405 compares the symbol determination result “x′ₙ₋ₐ” of the backward calculation and the symbol determination result “x″ₙ₋ₐ” of the forward calculation bit by bit. When the symbol determination result “x′ₙ₋ₐ” and the symbol determination result “x″ₙ₋ₐ” are the same, the soft decision output unit 405 outputs the log likelihood ratio “λ′_{k,n-a}” as the soft decision result “λ_{k,n-a}.”

When the symbol determination result “x′ₙ₋ₐ” and the symbol determination result “x″ₙ₋ₐ” are different, the soft decision output unit 405 uses the sign function “sgn” to acquire the sign of the log likelihood ratio “λ′_{k,n}” in Equation (24). The soft decision output unit 405 may acquire the sign of the log likelihood ratio “λ_{k,n}” of Equation (1) instead of acquiring the sign of the log likelihood ratio “λ′_{k,n}” of Equation (24). The soft decision output unit 405 calculates a new soft decision result “λ_{k,n-a}” based on a sign opposite to the sign of the log likelihood ratio “λ′_{k,n},” a predetermined constant “A,” and a standard deviation “σ” of the noise distribution.

The soft decision result “λ_{k,n-a}” (log likelihood ratio) when the symbol determination result “x′ₙ₋ₐ” and the symbol determination result “x″ₙ₋ₐ” are the same and the new soft decision result “λ_{k,n-a}” (changed log likelihood ratio) when the symbol determination result “x′ₙ₋ₐ” and the symbol determination result “x″ₙ₋ₐ” are different are each expressed as in Equation (26).

$$\begin{matrix}[ Math . 26 ] & \\ {λ}_{k , n - a} = \{ \begin{matrix}- \frac{A}{2 {σ}^{2}} sgn ( {λ}_{k , n - a}^{′} ) , & {x}_{n - a}^{′} \neq {x}_{n - a}^{″} \\ {λ}_{k , n - a}^{′} , & {x}_{n - a}^{′} = {x}_{n - a}^{″}\end{matrix} & ( 26 )\end{matrix}$$

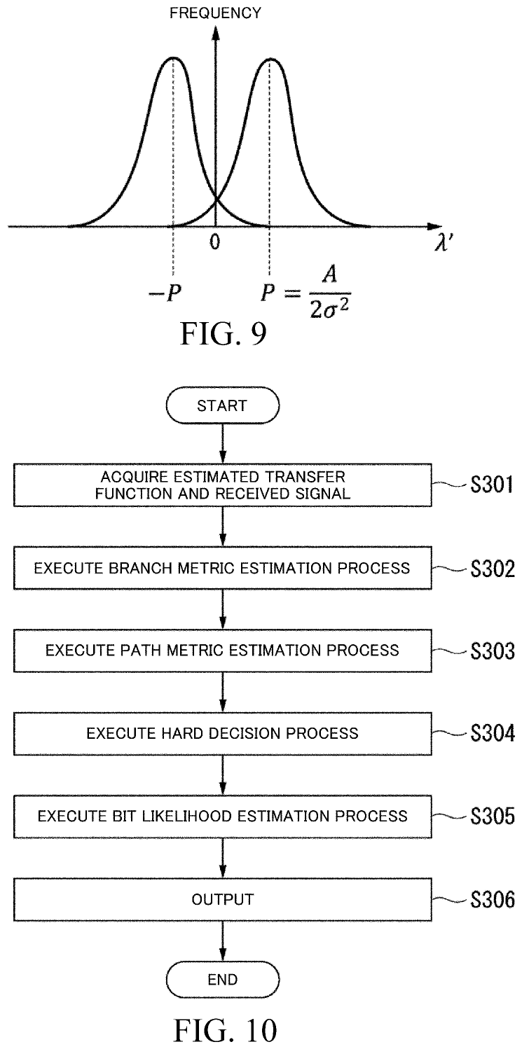

FIG. 9 is a flowchart showing a third example of a flow of processing executed by the soft decision device 4 according to the embodiment. The control unit 40 acquires the estimated transfer function stored in the storage unit 42 and the received signal acquired by the interface unit 41 (step S301). Next, the control unit 40 executes a branch metric estimation process (step S302). Next, the control unit 40 executes a path metric estimation process (step S303).

The control unit 40 generates a symbol determination result of backward calculation and a symbol determination result of forward calculation by executing a hard decision process (step S304). The control unit 40 executes a bit likelihood estimation process based on the symbol determination result of the backward calculation, the symbol determination result of the forward calculation, and a predetermined constant “A” (step S305). The control unit 40 acquires the likelihood estimated in the process of step S305 as a result of the soft decision. The control unit 40 controls the operation of the interface unit 41 and causes the interface unit 41 to output the likelihood “λ_{k,n-a}” estimated in step S305 (step S306).

As described above, the control unit 40 changes the likelihood “λ_{k,n}” based on a sign “−” opposite to a sign of the estimated likelihood (sgn(λ′_{k,n})), a predetermined constant, and a standard deviation “σ” when a determination result “x′ₙ” of the nth symbol obtained by calculation in order from the (n+a)th (for example, a=1) of the transmission signal to the nth is different from a determination result “x″ₙ” of the nth symbol obtained by calculation in order from the nth of the transmission signal to the (n+a)th. The predetermined constant “A” is determined as “2σ²P” based on a likelihood “P” indicating a positive peak of the distribution and the standard deviation “σ.”

In this way, in the second embodiment, the log likelihood ratio (bit likelihood) “λ_{k,n-a}” for each bit is made different depending on whether the symbol determination result “x′ₙ₋ₐ” and the symbol determination result “x″ₙ₋ₐ” are the same and the symbol determination result “x′ₙ₋ₐ” and the symbol determination result “x″ₙ₋ₐ” are different. This makes it possible to further improve the normalized general mutual information (NGMI).

Furthermore, compared to the first embodiment, it is possible to estimate the symbols of the transmission signal with higher accuracy.

### Modification Example of Second Embodiment

FIG. 10 is a diagram showing an example of a bit likelihood histogram in the embodiment. The soft decision output unit 405 acquires a predetermined positive constant “A” from the memory 92, for example. As exemplified in Equation (26), the absolute value of the soft decision result is expressed as “A/2σ².”

Regardless of the variance “σ²” of the bit likelihood histogram, the optimum value of the positive constant “A” tends to be constant for each transmission system and demodulation method. Further, the optimal value of the positive constant “A” is close to the positive likelihood “P (=A/2σ²)” which indicates the peak of the bit likelihood histogram. Therefore, a positive constant “A” may be determined in advance based on the likelihood “P (=A/2σ²).”

### Experimental Results

An example of results of an experiment using the soft decision device 4 will be described.

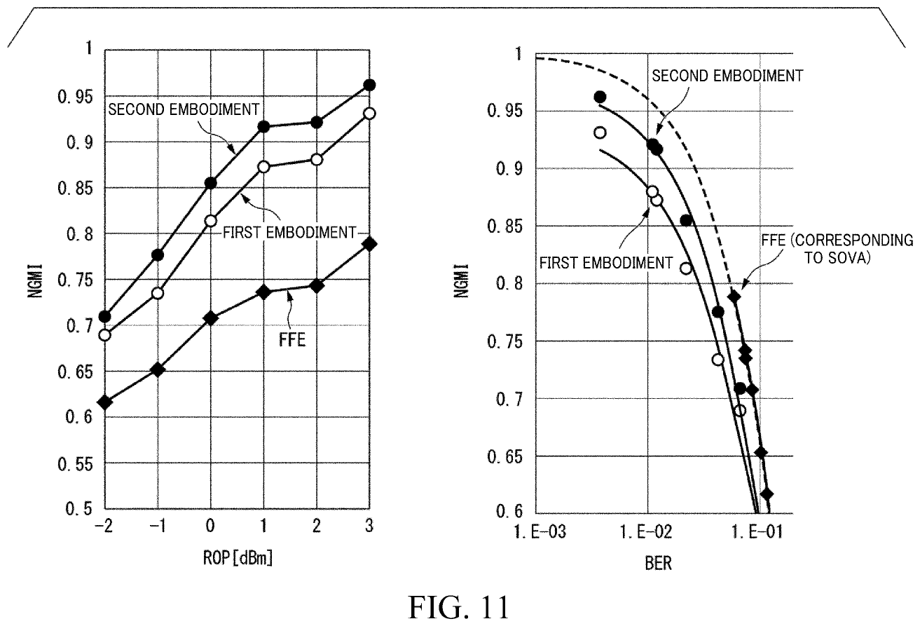

FIG. 11 is a third diagram showing an example of experimental results in the embodiment. In FIG. 11, the symbol multilevel degree “M” is 4, for example. The storage length “d” is 5, for example. The number of tracebacks “T” is 20, for example. The predetermined positive constant “A” in the second embodiment is 0.018, for example.

The number “M_{d}” of path metrics required to calculate the log likelihood ratio “λ” in the first embodiment is 1024, for example. The number “2M_{d}” of path metrics required to calculate the log likelihood ratio “λ” in the second embodiment is 1024, for example. The number “M^{d+1}T” of path metrics required to calculate the log likelihood ratio “λ” in the FFE scheme is 81920, for example.

The left graph in FIG. 11 shows the relationship between received optical power (ROP) and normalized general mutual information (NGMI) for the FFE scheme, the NL-MLSE scheme in the first embodiment, and the NL-MLSE scheme in the second embodiment.

Both the received optical power of the NL-MLSE scheme in the first embodiment and the received optical power of the NL-MLSE scheme in the second embodiment achieve higher normalized general mutual information than the FFE scheme. When the ROP is 3 dBm, the normalized general mutual information is improved by about 18% in the first embodiment. Further, in the second embodiment, the normalized general mutual information is improved by about 22%.

The right graph in FIG. 11 shows the relationship between a bit error rate (BER) and normalized general mutual information (NGMI) for the FFE scheme, the NL-MLSE scheme in the first embodiment, and the NL-MLSE scheme in the second embodiment. In the right graph, the broken line overlapping the results of the FFE scheme represents the theoretical curve of the additive white Gaussian noise (AWGN) channel. The performance represented by the theoretical curve corresponds to the performance of the soft output Viterbi algorithm (SOVA) with a very large amount of calculations, when the same BER as the NL-MLSE scheme is obtained.

The FFE scheme cannot achieve a bit error rate of “0.8.” On the other hand, the NL-MLSE scheme in the first embodiment can achieve a bit error rate of “0.931.” Furthermore, the NL-MLSE scheme in the second embodiment can achieve a bit error rate of “0.962.” In this way, the optical transmission system 100 in the second embodiment can achieve performance close to the normalized general mutual information “0.985” by the soft output Viterbi algorithm with a smaller amount of calculations.

Although the embodiments of the present invention have been described in detail with reference to the drawings, specific configurations are not limited to the embodiments, and include design and the like within the scope of the present invention without departing from the gist of the present invention.

### REFERENCE SIGNS LIST

100 Optical transmission system
1 Transmitter
2 Transmission line
3 Receiver
4 Soft decision device
40 Control unit
41 Interface unit
42 Storage unit
91 Processor
92 Memory
401 Transfer function estimation unit
402 Branch metric processing unit
403 Path metric processing unit
404 Hard decision output unit
405 Soft decision output unit

1. A soft decision device that performs a soft decision on a main symbol that is an (n+1)th symbol (n is an integer from 1 to N, N is an integer of 1 or more) of a transmission signal with a symbol multilevel degree of m (m is an integer of 2 or more), the soft decision device comprising:
a controller that executes
a branch metric estimation process of estimating a branch metric, which is a distance that is obtained by a Viterbi algorithm, is indicated by a predetermined distance function, and indicates a likelihood of transition from an nth symbol of the transmission signal to each candidate for the (n+1)th symbol, based on an estimated transfer function that is a previously obtained estimation result of a transfer function of a transmission line through which the transmission signal propagates and a received signal that is a result of reception of the transmission signal,
a path metric estimation process of estimating a path metric, which is a sum of a distance that is obtained by the Viterbi algorithm, is indicated by a predetermined distance function, and indicates a likelihood that each candidate for the (n+1)th symbol of the transmission signal is a symbol of the transmission signal and a distance of first to nth remaining paths of the transmission signal, based on a result of the branch metric estimation process, and
a bit likelihood estimation process of estimating a likelihood that a kth bit (k is an integer from 1 to m) in the (n+1)th symbol of the transmission signal is a predetermined bit by using the path metric of each candidate for the (n+1)th symbol of the transmission signal obtained by the path metric estimation process, and without using path metrics other than the path metric of each candidate for the (n+1)th symbol of the transmission signal,
wherein the controller acquires the likelihood estimated by the bit likelihood estimation process as a result of the soft decision.

2. The soft decision device according to claim 1, wherein the controller estimates the likelihood by also using a standard deviation of a distribution of noise added to the transmission signal on the transmission line.

3. The soft decision device according to claim 2, wherein the standard deviation is obtained based on a difference between the received signal and a result of applying the estimated transfer function to correct data indicating a correct answer of the transmission signal.

4. The soft decision device according to claim 2, wherein the controller changes the likelihood based on a sign opposite to a sign of the estimated likelihood, a predetermined constant, and the standard deviation when a determination result of the nth symbol obtained by calculation in order from the (n+1)th of the transmission signal to the nth is different from a determination result of the nth symbol obtained by calculation in order from the nth of the transmission signal to the (n+1)th.

5. The soft decision device according to claim 4, wherein the predetermined constant is determined based on the likelihood indicating a positive peak of the distribution and the standard deviation.

6. A soft decision method for performing a soft decision on a main symbol that is an (n+1)th symbol (n is an integer from 1 to N, N is an integer of 1 or more) of a transmission signal with a symbol multilevel degree of m (m is an integer of 2 or more), the soft decision method comprising:
a control step of executing
a branch metric estimation process of estimating a branch metric, which is a distance that is obtained by a Viterbi algorithm, is in a predetermined distance function, and indicates a likelihood of transition from an nth symbol of the transmission signal to each candidate for the (n+1)th symbol, based on an estimated transfer function that is a previously obtained estimation result of a transfer function of a transmission line through which the transmission signal propagates and a received signal that is a result of reception of the transmission signal,
a path metric estimation process of estimating a path metric, which is a sum of a distance that is obtained by the Viterbi algorithm, is in a predetermined distance function, and indicates a likelihood that each candidate for the (n+1)th symbol of the transmission signal is a symbol of the transmission signal and a distance of first to nth remaining paths of the transmission signal, based on a result of the branch metric estimation process, and
a bit likelihood estimation process of estimating a likelihood that a kth bit (k is an integer from 1 to m) in the (n+1)th symbol of the transmission signal is a predetermined bit by using the path metric of each candidate for the (n+1)th symbol of the transmission signal obtained by the path metric estimation process, and without using path metrics other than the path metric of each candidate for the (n+1)th symbol of the transmission signal,
wherein the control step includes acquiring the likelihood estimated by the bit likelihood estimation process as a result of the soft decision.

7. A non-transitory computer readable storing a program for causing a computer to function as the soft decision device according to claim 1.
